(19) United States
(12) Patent Application Publication
(10) Pub. No.: US 2005/0059278 A1
(43) Pub. Date: Mar. 17, 2005

(54) Card edge connector with improved terminals

(76) Inventor: Chi Zhang, Kunsan (CN)

Correspondence Address: WEI TE CHUNG;FOXCONN INTERNATIONAL, INC., 1650 MEMOREX DRIVE, SANTA CLARA, CA, 95050, US

(21) Appl. No.: 10/943,663

(22) Filed: Sep. 16, 2004

(30) Foreign Application Priority Data
Sep. 17, 2003 (CN) 03279391. X

(51) Int. Cl. H01R 12/00; H05K 1/00; H01R 13/62

(52) U.S. Cl. 439/83

(57) ABSTRACT

A card edge connector (1) includes an insulative housing (2), a row of upper and lower terminals (3, 4) retained in the housing (2). Each of the upper and lower terminals (3, 4) forms a retaining portion (33, 43), a contacting arm (30, 40) and a connection portion (32, 42) extending form opposite side of the same end of the retaining portion (33, 43), and a soldering portion (31, 41) connecting to a free end of the connection portion (32, 42). The soldering portion (31, 41) is parallel to the retaining portion (34, 43). Furthermore, the soldering portion (31, 41) includes a first soldering tail (311, 411) that extends from the end of the connecting portion (32, 42) in a direction away from the retaining portion (33, 43), and a second soldering tail (312, 412) opposite the first soldering tail (311, 411).

### BACKGROUND OF THE INVENTION

1. Field of the Invention

The present invention relates to an electrical connector, and particularly to a card edge connector for being surface mounted onto a printed circuit board (PCB).

2. Description of Related Art

With the continuing trend of the computer industry toward miniaturization, notebook and hand held computers require an efficient use of internal space to include the necessary hardware within a housing of limited size. With conventional technology, a printed circuit board is commonly provided with through holes for connecting electrical components on one surface with components on the opposite surface of the PCB. However, such arrangement occupies too much space in the notebook computer. Therefore, a surface mounting technology (SMT) has been introduced for using every possible area of the PCB effectively.

U.S. Pat. No. 5,839,913 (the '913 patent) issued to Fumikura discloses an edge connector surface mounted onto a printed circuit board. Referring to FIG. 7 of the '913 patent, the edge connector comprises a base part, a pair of arm parts which protrude in a forward direction from both ends of the base part, and latch members which are attached to the arm parts, and a plurality of terminals installed in respective rows in the base part and forming two terminal groups (upper and lower). The terminals have base portions and tine parts which are connected to a PCB (not shown in the figure) by soldering. One problem about this edge connector, or the like, is that since connections of the base portions and the tine parts of the terminals are comparatively smooth, wicking of the solder from the tine parts 26a and 28a to the contact parts of the terminals is significantly serious. Furthermore, after surface mounting of the edge connector to one side of the PCB, the PCB with the associated connector is handled in an upside-down manner to surface mount other components on the other side of the PCB, which results in a tendency of the liquid solder or excess solder to flow downwardly along the surface of the terminals. Consequently, the solder paste between the tine parts and the PCB is not sufficient and the contact parts of the terminals are contaminated by the melted solder, which will adversely affect the electrical connection of the edge connector with the PCB and a corresponding electronic card mated in the edge connector.

Therefore, an improved card edge connector is required to overcome the disadvantages of the prior art.

### SUMMARY OF THE INVENTION

Accordingly, an object of the present invention is to provide a card edge connector with improved terminals that can prevent the solder from wicking and reflowing from the soldering portion to the contacting portion of the terminals.

In order to achieve the object set forth, a card edge connector in accordance with the present invention, comprises an insulative housing defining a row of upper passageways and a row of lower passageways, a row of upper terminals and a row of lower terminals retained in the upper and lower passageways, respectively. Each of the upper and lower terminals comprises a retaining portion, a contacting arm and a connection portion extending from opposite sides of the same end of the retaining portion, and a soldering portion connecting to the connection portion. The soldering portion is parallel to the retaining portion. Furthermore, the soldering portion includes a first soldering tail that extends from the end of the connecting portion in a direction away from the retaining portion, and a second soldering tail opposite the first one. Each of the upper and lower terminals defines a notch between the connection portion and the second soldering tail. Each of the upper terminals comprises a tab projecting from the connection portion opposite to the retaining portion. Each of the lower terminals defines a cutout in the connecting portion opposite to the retaining portion.

Other objects, advantages and novel features of the invention will become more apparent from the following detailed description of the present embodiment when take in conjunction with the accompany drawings.

### BRIEF DESCRIPTION OF THE DRAWINGS

FIG. 1 is an exploded perspective view of a card edge connector in accordance with the present invention;

FIG. 2 is an assembled view of the card edge connector shown in FIG. 1;

FIG. 3 is a top planar view of the card edge connector shown in FIG. 1;

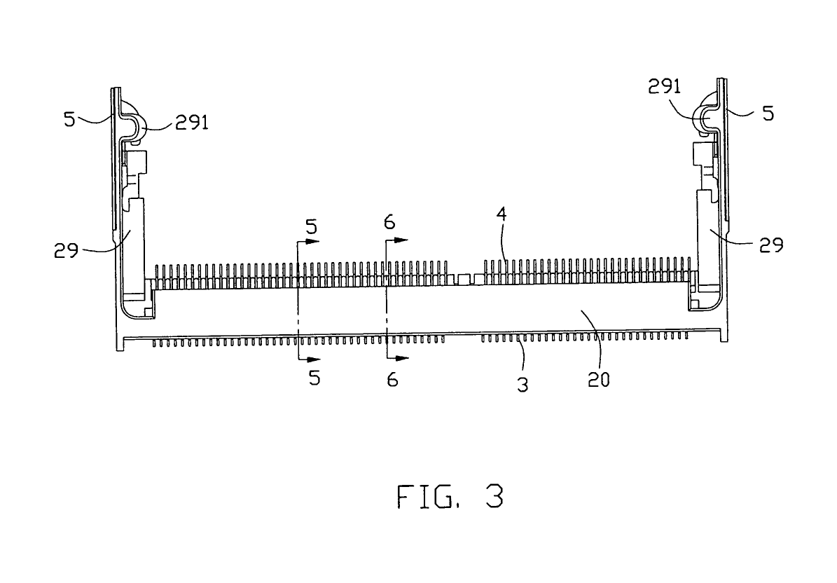

FIG. 4 is a side elevational view of one terminal shown in FIG. 2;

FIG. 5 is a partially enlarged cross-sectional view taken along line 5-5 of FIG. 3; and

FIG. 6 is a partially enlarged cross-sectional view taken along line 6-6 of FIG. 3.

### DETAILED DESCRIPTION OF PREFERRED EMBODIMENTS

Reference will now be made to the drawings to describe the present invention in detail.

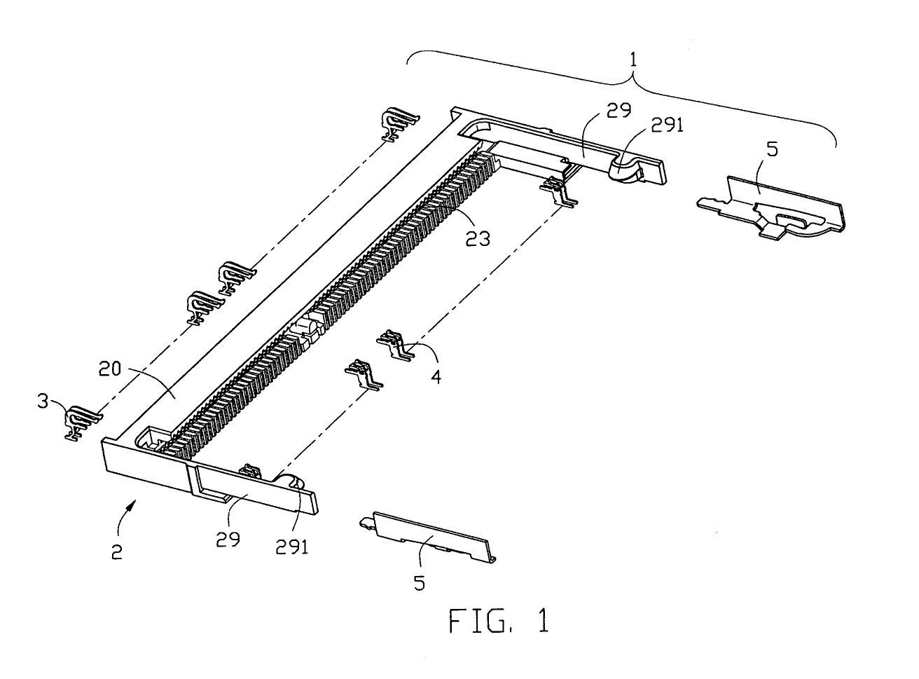

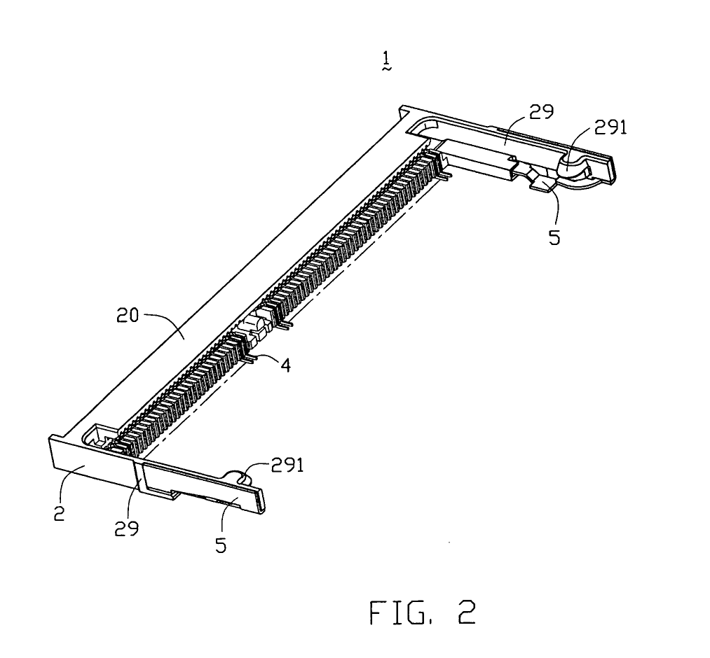

Referring to FIGS. 1 and 2, a card edge connector 1 in accordance with the present invention comprises an elongate insulative housing 2, a row of upper terminals 3 and a row of lower terminals 4 respectively retained in the insulative housing 2, and a pair of metal latches 5 attached to opposite ends of the housing 2.

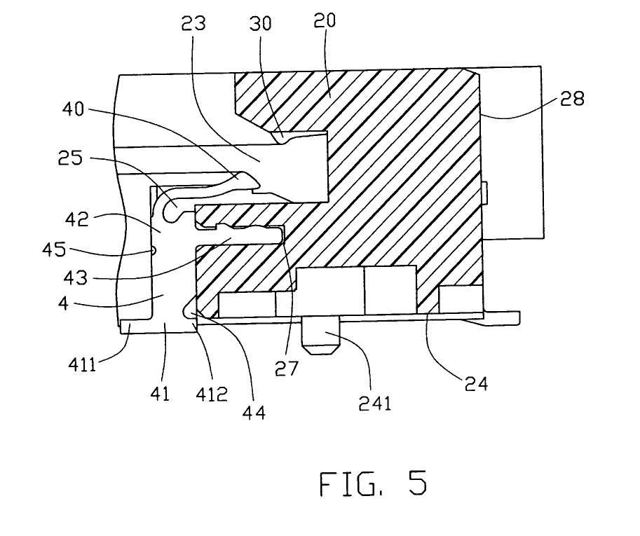

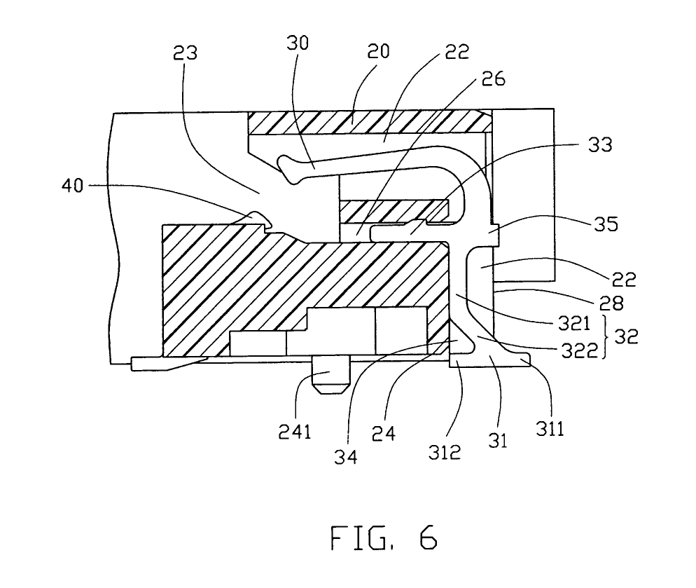

Together referring to FIGS. 5 and 6, the housing 2 includes an elongate base 20 and a pair of latching members 29 extending forwardly from opposite ends of the base 20, respectively. The base 20 defines a central slot 23 for receiving an electronic card (not shown) thereinto, a mounting surface 24 to be mounted on an underlying PCB (not shown), and a rear surface 28 connected with the mounting surface 24. Additionally, the base 20 defines a row of upper passageways 22, retaining channels 26 communicating with the slot 23 and the rear surface 28 for receiving the row of upper terminals 3, a row of lower passageways 25 communicating with the slot 23 and the mounting surface 24, and a row of lower retaining recesses 27 for receiving the row of lower terminals 4. Further, the base 20 is formed with a pair of positioning posts 241 extending from the bottom surface 24 downwardly for being received in corresponding holes of the PCB. Each of the latching members 29 comprises a latching portion 291 for latching /ejecting the electronic card. The metal latches 5 are respectively fastened to the latching members 29 to strengthen the intensity of the latching members 29.

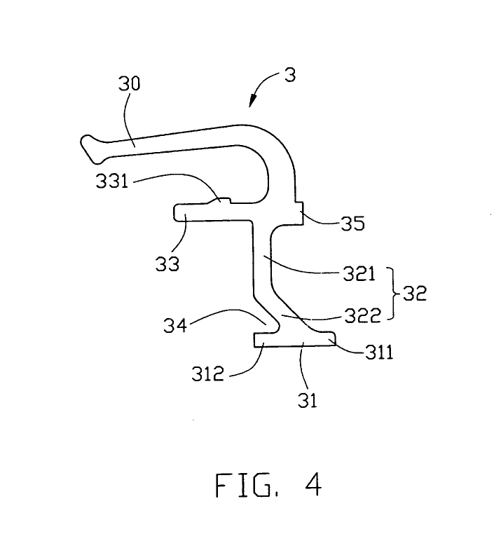

Referring to FIGS. 4 and 6, the row of upper terminals 3 are inserted into corresponding upper passageways 22 of the housing 2 and are adapted for conductively contacting with corresponding gold fingers on one side of the electronic card. The upper terminal 3 comprises a retaining portion 33, a contacting arm 30 and a connection portion 32 extending from opposite sides of the same end of the retaining portion 33, and a soldering portion 31 connecting to the connection portion 32. The retaining portion 33 is received in the corresponding retaining channel 26 of the housing 2. The retaining portion 33 is formed with a barb 331 for interferentially engaging with the housing 2. The contacting arm 30 first extends upwardly from the end of the retaining portion 33 and then forwardly to be approximately parallel to the retaining portion 33 and partly into the central slot 23. The connection portion 32 includes a first connection section 321 perpendicularly connecting with the retaining portion 33, a second connection section 322 connecting with the soldering portion 31. Furthermore, the soldering portion 31 is parallel to the retaining portion 33, and includes a first soldering tail 311 extending from a end of the second connection portion 322 in a direction away from the retaining portion 33, and a second soldering tail 312 opposite the first soldering tail 311. Furthermore, each of the upper terminals 3 comprises a notch 34 between the second soldering tail 312 and the second connection section 322, and a tab 35 projecting from the first connection section 321 opposite to the retaining portion 33.

Referring to FIG. 5, the row of lower terminals 4 most similar to the upper terminals 3 are inserted into corresponding lower passageways 25 of the housing 2 and each comprises a retaining portion 43 retained in the retaining recesses 27, a contacting arm 40 and a connection portion 42 extending from opposite sides of the same end of the retaining portion 43, and a soldering portion 41 connecting to the connection portion 42. The contacting arm 40 is shorter than the contacting arm 30 of the upper terminal 3 and the connection portion 42 is wider than the connection portion 32 of the upper terminal 3, for providing enough normal force for securing a reliable connection with the inserted electronic card. The soldering portion 41 includes a first soldering tail 411 extending from the end of connection portion 42 in a direction away from the retaining portion, and a second soldering tail 412 opposite the first one 411. Additionally, each of the lower terminals defines a notch 44 between the connection portion 42 and the second soldering tail 412, a cutout 45 in the connecting portion 42 opposite to the retaining portion 43.

The notches 34, 44, the tab 35, and the cutout 45 all can prevent solder from wicking and reflowing from the soldering portion 31, 41 toward the contacting portion 30, 40. Furthermore, the connection portion 32 and 42 may also provide anti-wicking coating on surfaces thereof to further prevent the wicking of solder. One preferred material for this purpose is nickel plating. With the above arrangements, the edge card connector 1 can be electrically connected with the corresponding electronic card and the PCB reliably.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A card edge connector for being surface mounted on a printed circuit board (PCB), comprising:
an insulative housing comprising an elongate base having a central slot, and a plurality of passageways; and
a plurality of terminals retained in the passageways, respectively, each of the terminals comprising a retaining portion, a contacting arm and a connection portion both extending from opposite sides of one end of the retaining portion, and a soldering portion connecting to the connection portion, the soldering portion comprising a first soldering tail which extends from the connecting portion in a direction away from the retaining portion, and a second soldering tail opposite the first soldering tail.

2. The card edge connector as claimed in claim 1, wherein the soldering portion is parallel to the retaining portion.

3. The card edge connector as claimed in claim 2, wherein the contacting arm first extends upwardly from the end of the retaining portion and then extends in a direction approximately parallel to the retaining portion partly into the central slot.

4. The card edge connector as claimed in claim 3, wherein each of the terminals comprises a notch between the second soldering tail and the connection portion.

5. The card edge connector as claimed in claim 4, wherein each of the passageways comprises a row of upper passageways and a row of lower passageways, and the terminals comprise a row of upper terminals and a row of lower terminals received in the upper and lower passageways, respectively.

6. The card edge connector as claimed in claim 5, wherein each of the upper terminals comprises a tab projecting from the connection portion opposite to the retaining portion.

7. The card edge connector as claimed in claim 5, wherein each of the lower terminals comprises a cutout in the connecting portion opposite to the retaining portion.

8. A terminal of an electrical connector which is surface mounted on a printed circuit board, comprising:
a retaining portion;
a contacting arm and a connection portion extending from opposite sides of one end of the retaining portion;
a soldering portion connecting to the connection portion, the soldering portion comprising a first soldering tail which extends from the connecting portion in a direction away from the retaining portion, and a second soldering tail opposite the first soldering tail.

9. The terminal as claimed in claim 8, wherein the soldering portion is parallel to the retaining portion.

10. The terminal as claimed in claim 9, wherein the contacting arm first extends upwardly from the end of the retaining portion and then extends in a direction approximately parallel to the retaining portion.

11. The terminal as claimed in claim 10, wherein the terminal comprises a notch between the second soldering tail and the connection portion.

12. The terminal as claimed in claim 111, wherein the terminal comprises a tab projecting from the connection portion opposite to the retaining portion thereof.

13. The terminal as claimed in claim 12, wherein the terminal comprises a cutout in the connecting portion opposite to the retaining portion thereof.

14. An electrical connector for being surface mounted on a printed circuit board (PCB), comprising:
an insulative housing having a plurality of terminal disposed therein, each of the terminals comprising a horizontal soldering portion and a connection portion extending upwardly from the horizontal soldering portion, one vertical edge section of said connection portion abutting against the housing, a notch formed in said vertical edge section adjacent to the soldering portion so as to form a V-like configuration on a lower portion of the connection portion adjacent to the soldering portion.

15. The electrical connector as claimed in claim 14, wherein said lower portion is linked to a middle portion of the soldering portion.
